(19) United States
(12) Patent Application Publication
(10) Pub. No.: US 2026/0236631 A1
(43) Pub. Date: Aug. 13, 2026

(54) METHOD OF ESTIMATING DYNAMIC COEFFICIENT OF ELECTRIC VEHICLE AND PREDICTING ENERGY CONSUMPTION BY UTILIZING SPEED LOG DATA AND PHYSICS-INFORMED NEURAL NETWORK

(71) Applicant: SUNY Korea Research and Business Development Foundation, Incheon (KR)

(72) Inventor: Jong Seong CHOI, Incheon (KR)

(21) Appl. No.: 19/290,373

(22) Filed: Aug. 5, 2025

(30) Foreign Application Priority Data
Feb. 12, 2025 (KR) 10-2025-0017752

(51) Int. Cl. G06F 30/15; G06F 30/27

(52) U.S. Cl. CPC G06F 30/15; G06F 30/27

(57) ABSTRACT

Provided is a method of estimating a dynamic coefficient of an electric vehicle and predicting energy consumption by utilizing speed log data and a physics-informed neural network enabling derivation of a physics-informed neural network for predicting a dynamic parameter and accurate prediction of instantaneous battery power and cumulative energy consumption based thereon including collecting log data for predicting energy consumption of the electric vehicle in a processor for predicting energy consumption of the electric vehicle using a model including a physics-informed neural network, deriving a dynamic model for predicting battery power dynamics of the electric vehicle, setting a loss function of the derived dynamic model, training and optimizing an energy consumption measurement model, which is a physics-informed neural network generated based on the set loss function, and predicting cumulative energy consumption using the energy consumption measurement model, which is the optimized physics-informed neural network.

### BACKGROUND OF THE INVENTION

### Field of the Invention

The present invention relates to accurate prediction of electric vehicle energy consumption, and provides essential information for development of a new navigation system, such as route optimization to a destination, suggestion of a charging location and time, and an optimal speed. Technical originality lies in predicting energy consumption with high accuracy by utilizing only driving log data recorded from a motor without attaching various sensors for measuring major energy consumption parameters (weight, air temperature, drag coefficient, road roughness, etc.) and combining the data with a physics-informed neural network. Existing artificial intelligence (AI) technology is highly dependent on data, which limits development of accurate prediction models. However, by applying the physics-informed neural network, an existing mathematical model is utilized in a normalization process of the neural network, dramatically increasing accuracy of a training result. The present invention utilizes this to predict electric vehicle energy, and more accurately predicts remaining energy, that is, a remaining all-electric range, using only first few minutes of electric vehicle driving log data, which has been experimentally proven in the present invention using two types of Tesla vehicles.

### Description of the Related Art

Electric vehicles (EVs) are increasingly being adopted due to environmental concerns, technological advancements, and government support policies, which are driving rapid market growth. EV sales are expected to reach 145 million units by 2030. As EV adoption accelerates, effective energy management is essential to optimize energy consumption, which is critical to maximizing efficiency and performance.

To address these problems, various optimization technologies have been studied. A comprehensive survey on EV battery optimization by Acar et al. [E. Acar, S. Kardas, and M. Kumbasar, “A survey on design optimization of battery electric vehicle components, systems, and management,” Journal of Cleaner Production, vol. 280, 2024, pp. 1-14. DOI: 10.1016/j.jclepro.2020.123456.] discusses traditional methods such as dynamic programming, model predictive control, and heuristic algorithms, highlighting major limitations in real-time EV operation.

However, these electric vehicle energy efficiency prediction technologies have the following problems.

First, as a complex model, the technologies rely on detailed models of vehicle dynamics and battery operation, which are complex and computationally expensive to develop.

Second, dynamic programming may optimize sequential decisions, but faces the “curse of dimensionality”, where computational demands exponentially increase as the number of variables increases.

Third, the technologies have an issue of cost and real-time limitation, and are not suitable for real-time use due to high computational cost, which may lead to non-optimal performance in high-dimensional systems such as EVs.

Machine learning-based approaches are emerging as a potential solution to this problem, which have the potential to provide more efficient and scalable solutions. These advanced technologies may enable real-time energy optimization, thereby improving the overall performance and sustainability of EVs.

A current model predictive control (MPC) optimization model frequently treats a nonlinear system as a linear approximation, which may lead to inaccurate prediction when external disturbance significantly different from an assumption occurs. Heuristic methods such as genetic algorithms or particle swarm optimization may handle nonlinearities and complex constraints, but these methods require a lot of computational resources and may be insufficient to handle various dynamic scenarios of actual electric vehicle (EV) operations. These limitations highlight the need for more advanced adaptive optimization technologies that may better handle the complexity and dynamic nature of EV energy management.

Recent studies have attempted to address these challenges. Zhang [W. Zhang and Z. Zhang, “Optimization and solution method for electric vehicle charging and discharging load,” Energy Reports, vol. 7, 2021, pp. 45-58. DOI: 10.1016/j.egyr.2020.123456.] used an optimal control technique utilizing convex optimization and second-order cone relaxation to efficiently manage the charging and discharging loads of EVs, thereby improving power grid stability and reducing operating costs. Zhu et al. [C. Zhu, J. Wu, and X. Li, “Optimization strategies for real-time energy management of electric vehicles based on LSTM network learning,” Energy Reports, vol. 8, 2022, pp. 1022-1033. DOI: 10.1016/j.egyr.2022.10.349.] applied Long Short-Term Memory (LSTM) networks to optimize EV charging decisions by leveraging strength in processing time-series data, successfully reducing charging costs and improving grid load management. However, these methods rely on massive sensor data and have high computational costs, and may not always accurately reflect the dynamic characteristics of EV operation.

A physics-informed neural network (PINN), introduced by Raissi et al. [M. Raissi, P. Perdikaris, and G. E. Karniadakis, “Physics-informed neural networks: A deep learning framework for solving forward and inverse problems involving nonlinear partial differential equations,” Journal of Computational Physics, vol. 378, 2019, pp. 686-707. DOI: 10.1016/j.jcp.2018.10.045.], provides a promising alternative by directly integrating the laws of physics into neural network learning. The PINN has the potential to predict a solution to a partial differential equation (PDE), providing a more versatile and reliable framework for predicting a nonlinear model. In particular, the PINN seems particularly useful in a situation where data is sparse or incomplete. There is no research or invention yet that utilizes the PINN for analysis and prediction of electric vehicle energy.

A neural network has a remarkable ability to approximate various functions, and this is supported by the universal approximation theorem. According to this theorem, a feedforward neural network including a single hidden layer having a sufficient number of neurons may approximate any continuous function. This ability comes from a structure of the neural network. Each neuron computes a weighted sum of input values, applies a nonlinear activation function, and then passes a result to the next layer. By combining linear transformation and nonlinear transformation, the neural network transforms input data into a latent space, which is a type of process of encoding and decoding input to output.

A feedforward neural network having a single hidden layer may be considered. For input x∈Rnx in R^{nx}∈Rn, output f(x)f(x)f(x) of the network may be expressed as follows.

$$( x ) = {\sum }_{i = 1}^{m} {β}_{i} σ ( {\sum }_{j = 1}^{n} {α}_{i j} {x}_{j} + {b}_{i} ) + c \qquad [ Equation 1 ]$$

Here, σ(⋅) denotes an activation function, m denotes the number of neurons in the hidden layer, αᵢⱼ and βᵢ denote weights of an input layer and the hidden layer, respectively, bᵢ denotes a bias term in the hidden layer, and c denotes a bias term in an output layer. The universal approximation theorem asserts that, for a continuous function g(x) defined on a compact subset K of Rⁿ, for any ε>0, there exists a neural network having a finite number of neurons m, which may be approximated as follows.

$${sup}_{x ∈ K} \vert f ( x ) - g ( x ) \vert < ∈ \qquad [ Equation 2 ]$$

This means that, given a sufficient number of neurons and appropriate weights, g(x) may be approximated as closely as desired by the network.

The PINN is a model extended by integrating a known physical law into a learning process of a conventional neural network. This process provides a solution which is data-driven and consistent with a fundamental physical principle. Many natural and engineering systems are governed by partial differential equations (PDEs), and examples thereof include the Navier-Stokes equations for fluid flow or the Fourier heat equations for heat conduction. Traditionally, numerical methods such as the finite element method or the finite difference method are used to solve these PDEs, which are computationally expensive and may lead to discretization errors.

Even though neural networks are skillful at approximating complex functions, purely data-driven models may produce solutions that violate the laws of physics when trained using limited or noisy data. In addition, models trained using large datasets may suffer from overfitting, which may cause the networks to not generalize or adapt to new situations. To address these limitations, the PINN integrates a governing PDE directly into a neural network training process, providing a generalizable network that respects the laws of physics [M. Raissi, P. Perdikaris, and G. E. Karniadakis, “Physics-informed neural networks: A deep learning framework for solving forward and inverse problems involving nonlinear partial differential equations,” Journal of Computational Physics, vol. 378, 2019, pp. 686-707. DOI: 10.1016/j.jcp.2018.10.045.].

A physical system described by a PDE is considered and expressed as follows.

$$𝒩 ( u ( x , t ) ) = f ( x , t ) \qquad [ Equation 3 ]$$

Here, N denotes a nonlinear differentiation operator, u(x,t) denotes an unknown solution to be learned, and f(x,t) denotes a known function. The nonlinear differentiation operator (neural network) is used to approximate u(x,t), and a loss function L_{PINN} is defined as follows.

$${ℒ}_{PINN} = {\sum }_{i = 1}^{N} ‖ u ( {x}_{i} , {t}_{i} ) - {u}_{d a t a} ( {x}_{i} , {t}_{i} ) {‖}^{2} + λ {\sum }_{j = 1}^{M} ‖𝒩 ( u ( {x}_{j} , {t}_{j} ) ) - f ( {x}_{i} , {t}_{i} ) {‖}^{2} \qquad [ Equation 4 ]$$

Here, λ denotes a weighting parameter that balances an influence of a physical law based on data.

An excellent example of PINN application may be found in the field of robotics.

Dynamical systems are governed by nonlinear ODE systems. For example, the dynamics of a multi-joint robot arm is usually described by the following system.

$$M ( q ) \ddot{q} + V ( q , \dot{q} ) + G ( q ) = τ \qquad [ Equation 5 ]$$

Here, q denotes a generalized coordinate vector (angle), M(q) denotes an inertia matrix, V(q, q⁻) denotes the Coriolis force and the centrifugal force, G(q) denotes gravity, and T denotes generalized applied force (torque). This ODE describes how the applied force affects joint motion of the robot. However, the problem is that the real-time solution is computationally significantly intensive. Traditional numerical solutions may be slow or require simplifications that reduce model accuracy.

Nicodemus et al. [J. Nicodemus, J. Kneifl, J. Fehr, and B. Unger, “Physics-informed Neural Networks-based Model Predictive Control for Multi-link Manipulators,” IFAC-PapersOnLine, vol. 55, no. 20, pp. 331-336, 2022. doi: 10.1016/j.ifacol.2022.09.117.] demonstrated that using PINNs as an alternative model for controlling a six-degree-of-freedom robotic arm may significantly reduce computation time while maintaining accuracy required for real-time control.

$${ℒ}_{manipulator} = {ℒ}_{data} + {λ}_{1} {ℒ}_{dynamics} + {λ}_{2} {ℒ}_{constraints} \qquad [ Equation 6 ]$$

This loss function allows the PINN to train a model that fully respects the Lagrangian dynamics of the robotic arm. A model result is more robust and effective against disturbances than traditional methods.

For autonomous driving, accurate and reliable vehicle dynamics models are essential to ensure safe navigation under various road conditions. In another study by Kim et al. [T. Kim, H. Lee and W. Lee, “Physics Embedded Neural Network Vehicle Model and Applications in Risk-Aware Autonomous Driving Using Latent Features,” ?2022 IEEE/RSJ International Conference on Intelligent Robots and Systems (IROS), Kyoto, Japan, 2022, pp. 4182-4189, doi: 10.1109/IROS47612.2022.9981303.], the Pacejka tire model and dynamic bicycle model were integrated into a PINN framework to improve a control strategy for predicting vehicle behavior under various friction conditions (e.g., ice or wet roads).

$$m ( {\dot{v}}_{x} + {v}_{y} ψ ) = {F}_{x} \qquad [ Equation 7 ]$$

$$m ( {\dot{v}}_{y} + {v}_{x} ψ ) = {F}_{y} \qquad [ Equation 8 ]$$

$${I}_{z} \ddot{ψ} = {M}_{z} \qquad [ Equation 9 ]$$

Here, vₓ and v_{y} denote longitudinal and lateral velocities, ψ denotes a yaw angle of a vehicle, Fₓ and F_{y} denote longitudinal and lateral forces acting on the vehicle, M_{z} is the yaw moment, m denotes the mass of the vehicle, and I_{z} denotes the moment of inertia of the vehicle about a vertical axis.

The physics-informed neural network approximates a state of the vehicle over time s(t)=[vₓ, v_{y}, ψ, ψ⁻]^{T} using the following loss function.

$${ℒ}_{vehicle} = {ℒ}_{data} + λ {\sum }_{j = 1}^{m} {‖ {ℱ}_{r esiduals} ( \hat{s} ( {t}_{j} ) , u ( {t}_{j} ) ) ‖}^{2} \qquad [ Equation 10 ]$$

By applying the physics-informed neural network to an autonomous driving framework, it is possible to accurately capture lateral tire force, adapt to changes in road friction, and mitigate risks such as skidding or loss of control. As shown in the above studies, an actual state is approximated by effectively combining the neural network and the dynamics. By combining experimental data with physical laws, it is possible to predict an accurate and robust model that captures complex behavior while respecting the underlying physics.

Therefore, there is desire for technology that may accurately predict battery power and cumulative energy consumption of an electric vehicle by mitigating a complex model, dimensionality curse, cost, and real-time limitations that arise from existing technologies proposed for battery energy optimization.
(Patent Document 1) Republic of Korea Registered Patent No. 10-2353705 (Registered on Jan. 17, 2022) (SYSTEM AND METHOD FOR ANALYZING THE ENERGY EFFICIENCY OF A MOTOR VEHICLE, IN PARTICULAR OF AN APPARATUS OF THE MOTOR VEHICLE)
(Patent Document 2) Republic of Korea Registered Patent No. 10-2015168 (Registered on Aug. 21, 2019) (METHOD AND APPARATUS FOR ESTIMATING REMAINING RANGE OF ELECTRIC VEHICLE)

### SUMMARY OF THE INVENTION

Therefore, the present invention has been made to mitigate a complex model, dimensionality curse, cost, and real-time limitations that arise from existing technologies proposed for battery energy optimization of the above-mentioned general electric vehicle, and an object of the present invention is to provide a method of estimating a dynamic coefficient of an electric vehicle and predicting energy consumption by utilizing speed log data and a physics-informed neural network enabling derivation of a physics-informed neural network for predicting a dynamic parameter and accurate prediction of instantaneous battery power and cumulative energy consumption based thereon.

In accordance with the present invention, the above and other objects can be accomplished by the provision of a “method of estimating a dynamic coefficient of an electric vehicle and predicting energy consumption by utilizing speed log data and a physics-informed neural network”, the method including steps of
(a) collecting log data for predicting energy consumption of the electric vehicle in a processor for predicting energy consumption of the electric vehicle using a model including a physics-informed neural network,
(b) deriving a dynamic model for predicting battery power dynamics of the electric vehicle,
(c) setting a loss function of the dynamic model derived in step (b),
(d) training and optimizing an energy consumption measurement model, which is a physics-informed neural network generated based on the set loss function, and
(e) predicting cumulative energy consumption using the energy consumption measurement model, which is the physics-informed neural network optimized in step (d).

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a flowchart illustrating a method of estimating a dynamic coefficient of an electric vehicle and predicting energy consumption by utilizing speed log data and a physics-informed neural network according to the present invention;

FIG. 2 is an example of collecting log data of the electric vehicle;

FIG. 3 is an example of a free body diagram during motion of the electric vehicle;

FIG. 4 is a schematic diagram of a physics-informed neural network (PINN);

FIG. 5 is an example of PINN loss of Tesla Model 3 Long Range;

FIG. 6 is an example of PINN loss of Tesla Model S;

FIG. 7 is a PINN loss graph of Tesla Model 3 Long Range;

FIG. 8 is a PINN loss graph of Tesla Model S;

FIG. 9 is a schematic diagram of a Runge-Kutta Neural Network (RKNN);

FIG. 10 illustrates RKNN loss prediction;

FIG. 11 is an RKNN loss graph;

FIG. 12 is a battery power and energy prediction result of Tesla Model 3;

FIG. 13 is a battery power and energy prediction result of Tesla Model S;

FIG. 14 is an example of predicted parameters; and

FIG. 15 is an example of parameter comparison.

### DETAILED DESCRIPTION OF THE INVENTION

Hereinafter, a detailed description will be given of a method of estimating a dynamic coefficient of an electric vehicle (EV) and predicting energy consumption by utilizing speed log data and a physics-informed neural network according to a preferred embodiment of the present invention with reference to the attached drawings.

The terms or words used in the present invention described below should not be interpreted as being limited to usual or dictionary meanings thereof, and should be interpreted as meanings and concepts that conform to the technical idea of the present invention based on the principle that the inventor may appropriately define the concepts of the terms to describe the invention in the best way.

Therefore, the embodiments described in this specification and the configurations illustrated in the drawings are only preferred embodiments of the present invention and do not represent all of the technical ideas of the present invention. Therefore, it should be understood that there may be various equivalents and modified examples that may replace the embodiments at the time of filing this application.

The present invention estimates actual conditions such as motor efficiency, regenerative braking efficiency, vehicle mass, aerodynamic drag, and rolling resistance of an EV, and integrates these parameters to more precisely predict battery consumption of the EV using only minimal sensor input such as a vehicle speed and a time.

To train an EV-PINN generated in the present invention, data was collected from Tesla Model 3 Long Range and Tesla Model S, and the battery power dynamics were derived and incorporated into the network loss. After optimizing hyperparameters, instantaneous battery power was predicted, and then cumulative energy consumption was predicted using a Runge-Kutta Neural Network (RKNN).

This will be described in detail as follows.

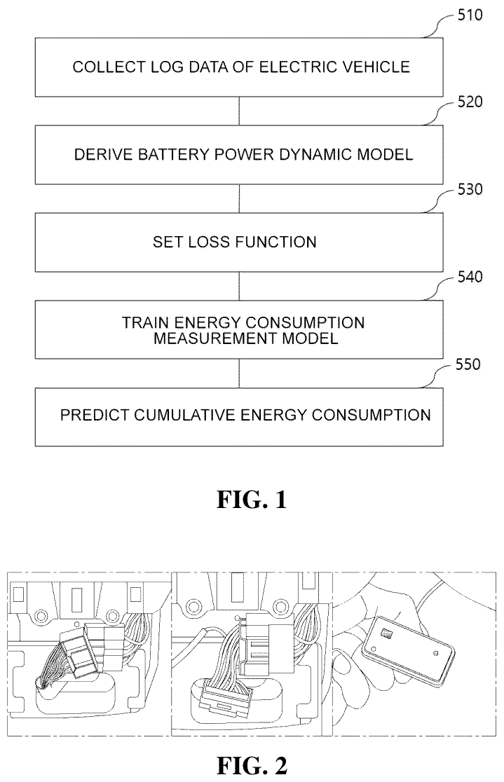

FIG. 1 is a flowchart illustrating a “method of estimating a dynamic coefficient of an EV and predicting energy consumption by utilizing speed log data and a physics-informed neural network” according to a preferred embodiment of the present invention, and may include step (a) of collecting log data for predicting energy consumption of an EV in a processor for predicting energy consumption of the EV using a model including a physics-informed neural network (510), step (b) of deriving a dynamic model for predicting battery power dynamics of the EV (520), step (c) of setting a loss function of the dynamic model derived in step (b) (530), step (d) of training and optimizing an energy consumption measurement model, which is a physics-informed neural network generated based on the set loss function (540), and step (e) of predicting cumulative energy consumption using the energy consumption measurement model, which is the physics-informed neural network optimized in step (d) (550).

Each of these steps represents a process executed in software by a processor that performs actual calculation, a processing function, etc. in a device having calculation and processing functions, such as a computer. Hereinafter, the entity that performs each step may be understood as the processor.

Each step will be described in detail as follows.

First, in step 510, the processor for predicting energy consumption of the EV using the model including the physics-informed neural network collects log data for predicting energy consumption of the EV.

FIG. 2 is an example of collecting the log data of the EV. Log data of Tesla Model 3 Long Range and Model S were collected through an OBD2 scanner. The collected data includes a vehicle speed (v), a time (t), a battery voltage (V), and a battery current (I). In order to minimize external variables, the log data was collected in a controlled environment. That is, the log data was collected on a flat road, on a windless day, in clear weather, and in a situation where there was no traffic.

Actual data of battery power was calculated using Ohm's law using the voltage and current from the log data, and this may be expressed as the following equation.

$${P}_{b attery , i} = {I}_{i} {V}_{i} \qquad [ Equation 11 ]$$

Next, in step 520, a dynamic model is derived to predict the battery power dynamics of the EV.

For example, a core ODE (ordinary differential equation) governing the dynamics of the battery power consumption of the EV is derived.

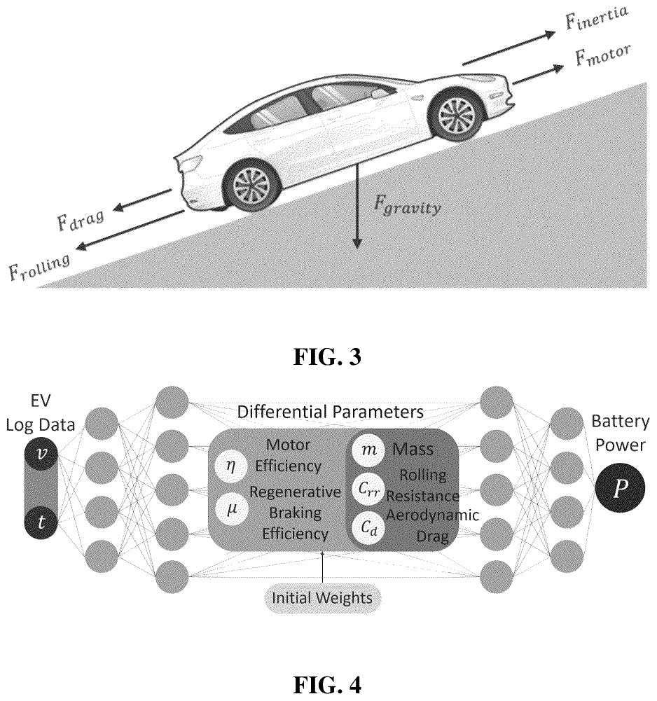

FIG. 3 is an example of a free body diagram during motion of the EV.

The following forces describe the dynamics of the EV.

$${F}_{drag} = \frac{1}{2} ρ {AC}_{d} {v}^{2} \qquad [ Equation 12 ]$$

$${F}_{rolling} = {C}_{rr} mg cos ( θ ) \qquad [ Equation 13 ]$$

$${F}_{gravity} = mg sin ( θ ) \qquad [ Equation 14 ]$$

$${F}_{inertia} = m \frac{dv}{dt} \qquad [ Equation 15 ]$$

$${F}_{motor} = \frac{η ( {P}_{battery} - {P}_{aux} )}{v} \qquad [ Equation 16 ]$$

[Equation 12] to [Equation 16] given above represent aerodynamic drag, rolling resistance, gravity, inertial force, and battery motor power, respectively. ρ denotes the air density, A denotes the frontal area of the vehicle, Cd denotes an aerodynamic drag coefficient, v denotes a vehicle speed, C_{π} denotes a rolling resistance coefficient, m denotes the vehicle mass, g denotes gravitational acceleration, θ denotes a road incline angle, and dv/dt denotes acceleration of the vehicle. η denotes motor efficiency, and Pₐᵤₓ denotes auxiliary power consumption of Tesla Model 3 LR and Model S, which are represented as ≈1100 W and ≈390 W, respectively, which are derived when the vehicle is in an idling state (v=0 and dv/dt=0). The total power required to move the vehicle is given by the sum of these forces, which is expressed as the following equation.

$${F}_{motor} = {F}_{drag} + {F}_{rolling} + {F}_{gravity} + {F}_{inertia} \qquad [ Equation 17 ]$$

When the motor force is set to be equal to the sum of the opposing forces, it is possible to obtain the following equation.

$$\frac{η ( {P}_{battery} - {P}_{aux} )}{v} = \frac{1}{2} ρ {AC}_{d} {v}^{2} + {C}_{rr} mg cos ( θ ) + mg sin ( θ ) + m \frac{d v}{d t} \qquad [ Equation 18 ]$$

When θ=0 (flat road) is set, and an equation is rearranged to solve for P_battery, it is possible to obtain a nonlinear ODE that governs battery power consumption of the EV, which is expressed as the following equation.

$${P}_{battery} = \frac{1}{η} ( \frac{1}{2} ρ {AC}_{d} {v}^{3} + {C}_{rr} mg v + m v \frac{d v}{d t} ) + {P}_{aux} \qquad [ Equation 19 ]$$

Regenerative braking recovers kinetic energy of the vehicle as electrical energy during deceleration of the vehicle, and thus needs to be considered. Power (P_regen) from regenerative braking is derived from kinetic energy of the vehicle.

$${P}_{regen} = - μ ( m v \frac{d t}{d t} ) , \frac{d t}{d t} < β \qquad [ Equation 20 ]$$

Here denotes regenerative braking efficiency, and β≈−0.045 m/s² is a regenerative braking deceleration threshold, which may be found from a deceleration state of the vehicle.

The overall dynamics considering regenerative braking are as follows.

$$𝒩 [ P ( v , t ) ; η , μ , {mC}_{rr} , {C}_{d} , ] = \frac{1}{η} ( \frac{1}{2} {ρ AC}_{d} {v}^{3} + {C}_{rr} mg v + mv \frac{d v}{d t} ( 1 - μ {I}_{a < β} ) ) + {P}_{aux} \qquad [ Equation 21 ]$$

I_(a<β) represents an indicator function that activates based on the regenerative braking deceleration threshold β.

Next, in step 530, the loss function of the derived dynamic model is set.

This loss function is important since the network needs to not only fit the vehicle log data, but also satisfy the physical constraints that govern the vehicle dynamics. The overall loss function, which is constructed similarly to an original PINN loss function, is expressed as follows for EV battery power consumption.

$${ℒ}_{power} = {\sum }_{i = 1}^{N} ( {‖ {P}_{d a t a}^{( i )} - {P}_{pred}^{( i )} ‖}^{2} + λ {‖ {P}_{physics}^{( i )} - {P}_{pred}^{( i )} ‖}^{2} ) \qquad [ Equation 22 ]$$

$${P}_{physics} = 𝒩 [ P ( v , t ) ; η , μ , m , {C}_{rr} , {C}_{d} ] \qquad [ Equation 23 ]$$

Here, P_{data}, P_{pred}, P_{physics}, and λ denote actual battery power in the log data, a prediction value of the network, theoretical battery power derived from the dynamics, and a weight, respectively. By minimizing this combined loss function, the network may not only learn to predict battery power based on the vehicle speed, but also estimate a key parameter that governs the vehicle dynamics. This approach assists in avoiding underfitting when data is scarce and mitigating overfitting by respecting physics. By incorporating a physics loss term, a local minimum value is added to an already complex and non-convex optimization landscape. To mitigate this, differentiation parameters are initialized to well-established values from online sources.

$${[ \begin{matrix}η \\ μ \\ m \\ {C}_{rr} \\ {C}_{d}\end{matrix} ]}_{initial , 3 LR} = [ \begin{matrix}0.7 \\ 0.5 \\ 1823 \\ 0.0096 \\ 0.23\end{matrix} ] \qquad [ Equation 24 ]$$

$${[ \begin{matrix}η \\ μ \\ m \\ {C}_{rr} \\ {C}_{d}\end{matrix} ]}_{initial , S} = [ \begin{matrix}0.7 \\ 0.5 \\ 2250 \\ 0.0096 \\ 0.23\end{matrix} ] \qquad [ Equation 25 ]$$

Regenerative efficiency (μ) was not available online, and thus 0.5 was set as an initial estimate. Vehicle mass and dimensions were taken from the official Tesla Model 3 and S Owner's Manual. Another parameter such as air density was set to ρ_air=1.17 kg/m³, and the frontal area was set to A_3LR=2.22 m² and A_S=2.40 m². Instead of searching the entire parameter space from the first, a realistic start point was provided to the PINN to achieve faster convergence to an accurate solution. The network took vehicle speed and time as inputs, and battery power as output. After numerous experiments, a convergent architecture includes four fully-connected layers each having 128 neurons and used a hyperbolic tangent (tanh) activation function. In addition, an Adam [D. P. Kingma and J. Ba, “Adam: A method for stochastic optimization,” in *Proc. 3rd Int. Conf. Learn. Representations (ICLR)*, San Diego, CA, USA, May 2015, pp. 1-15.] optimizer was applied, and different learning rates were assigned to parameters and layers. In addition, a physics loss weight coefficient was set to k=0.1. Initially, a loss value did not properly converge. However, by adjusting a learning rate, carefully initializing parameters, and fine-tuning a network architecture, it was possible to reduce the total loss and validation loss to about 1e-3.

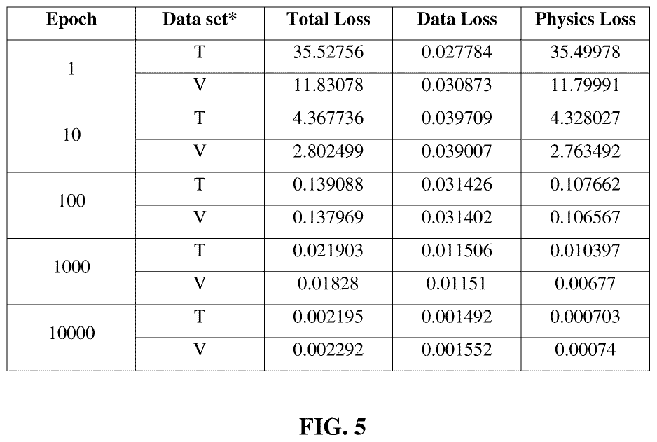

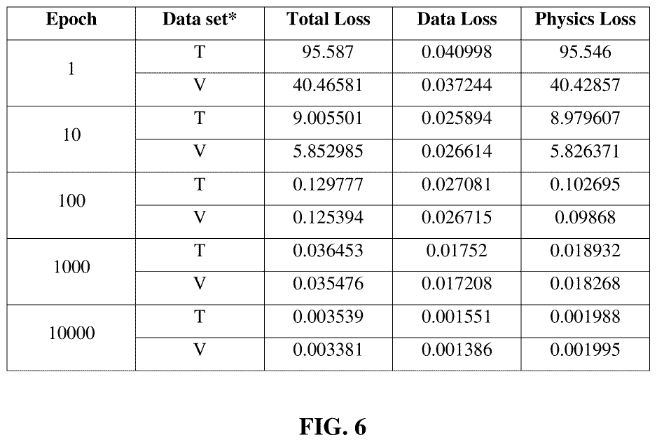

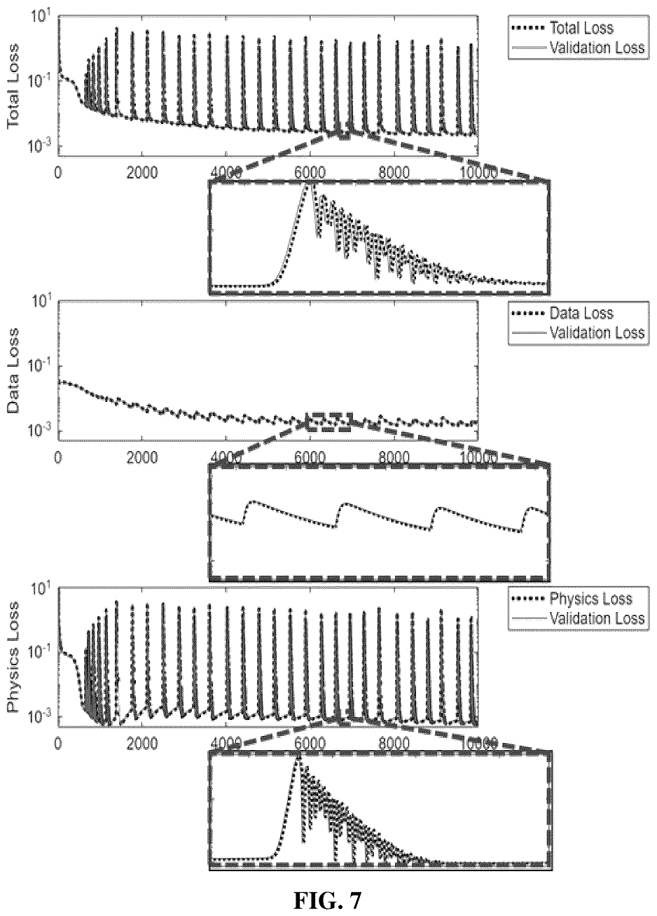

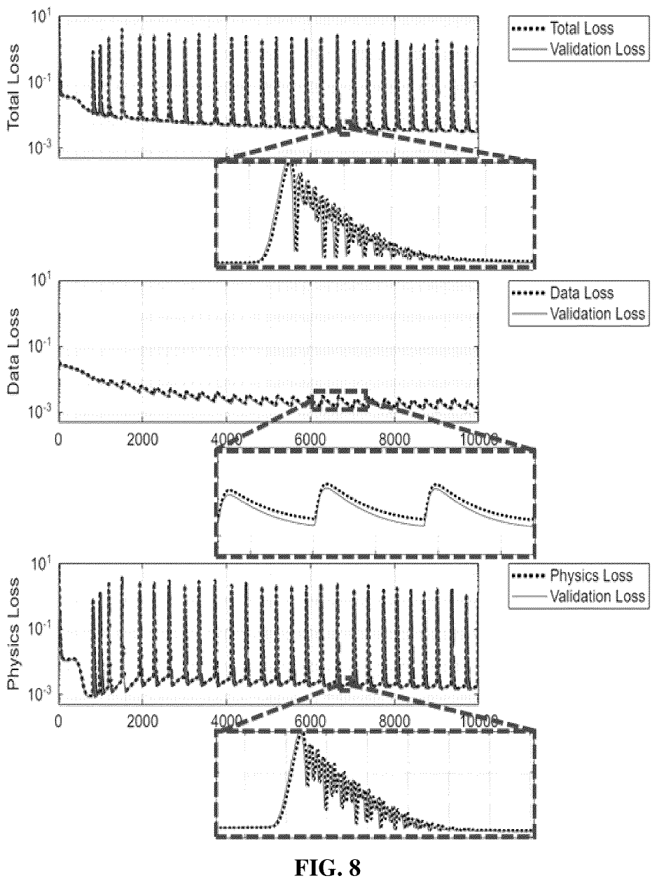

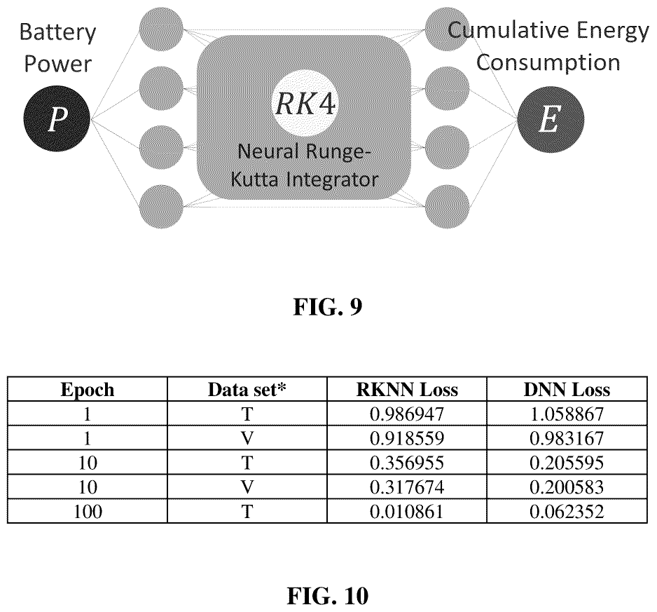

FIG. 5 is an example of PINN loss of Tesla Model 3 Long Range, FIG. 6 is an example of PINN loss of Tesla Model S, FIG. 7 is a PINN loss graph of Tesla Model 3 Long Range, and FIG. 8 is a PINN loss graph of Tesla Model S.

Next, in step 540, the RKNN, which is a physics-informed neural network generated based on the set loss function, is trained and optimized.

Modeling energy consumption of the EV requires integrating power over time. It has been ideal to directly use energy data provided from a vehicle log. However, available data only includes battery power. Since accurately integrating power dynamics is complex and computationally expensive, “the RKNN for high-accuracy dynamic system identification” has been used. Here, a Runge-Kutta subnetwork is embedded in the DNN to perform the fourth Runge-Kutta. This method has been proven to perform better in predicting an intermediate value than directly predicting an output value.

The RKNN may be simply implemented using PyTorch. Each subnetwork sequentially learns parameters k₁, k₂, k₃, and k₄ similarly to the traditional Runge-Kutta method. It has been found that the RKNN provides more stable training than the traditional DNN, and in particular, the RKNN may implement a deeper network without stability issues in the deeper network.

Through training this RKNN, an energy consumption prediction model is optimized.

Then, in step 550, cumulative energy consumption is predicted using the energy consumption measurement model, which is the optimized physics-informed neural network.

For example, energy E(t) is predicted at a future time t+Δt.

$${E}_{RK 4} ( t + Δ t ) = E ( t ) + \frac{Δ t}{6} ( {k}_{1} + 2 {k}_{2} + 2 {k}_{3} + {k}_{4} ) \qquad [ Equation 26 ]$$

$${k}_{1} = {𝒩}_{1} ( P ( t ) ) \qquad [ Equation 27 ]$$

$${k}_{2} = {𝒩}_{2} ( P ( t + \frac{Δ t}{2} , E ( t ) + \frac{Δ t}{2} {k}_{1} ) ) \qquad [ Equation 28 ]$$

$${k}_{3} = {𝒩}_{3} ( P ( t + \frac{Δ t}{2} , E ( t ) + \frac{Δ t}{2} {k}_{2} ) ) \qquad [ Equation 29 ]$$

$${k}_{4} = {𝒩}_{4} ( P ( t + Δ t , E ( t ) + Δ {tk}_{3} ) ) \qquad [ Equation 30 ]$$

Here, Nᵢ denotes a Runge-Kutta subnetwork in the RKNN, P denotes battery power, and Δt denotes a time interval. After directly integrating an RK4 method into a DNN to receive predicted battery power from the PINN, RK4 approximation of energy consumption may be predicted using the same. This process is performed with the following loss function.

$${ℒ}_{RK 4} = {\sum }_{i = 1}^{N} {‖ {E}_{RK 4}^{( i )} ( t + Δ t ) - {E}_{pred}^{( i )} ( t + Δ t ) ‖}^{2} \qquad [ Equation 31 ]$$

The present invention achieves optimal stability and accuracy by using three hidden layers and 32 neurons in each subnetwork and setting the learning rate to 1e-2, thereby reducing each of total loss and verification loss to 2e-4.

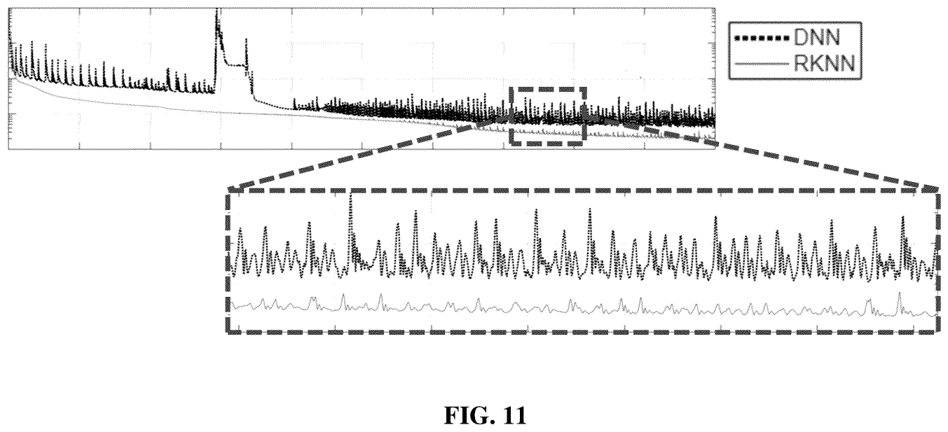

FIG. 10 illustrates RKNN loss prediction, and FIG. 11 is an RKNN loss graph.

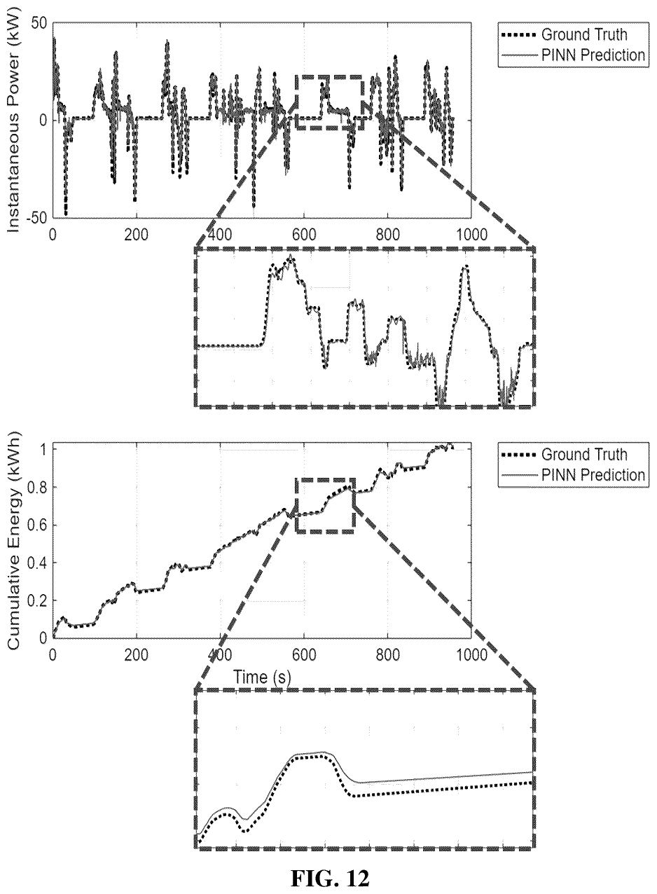

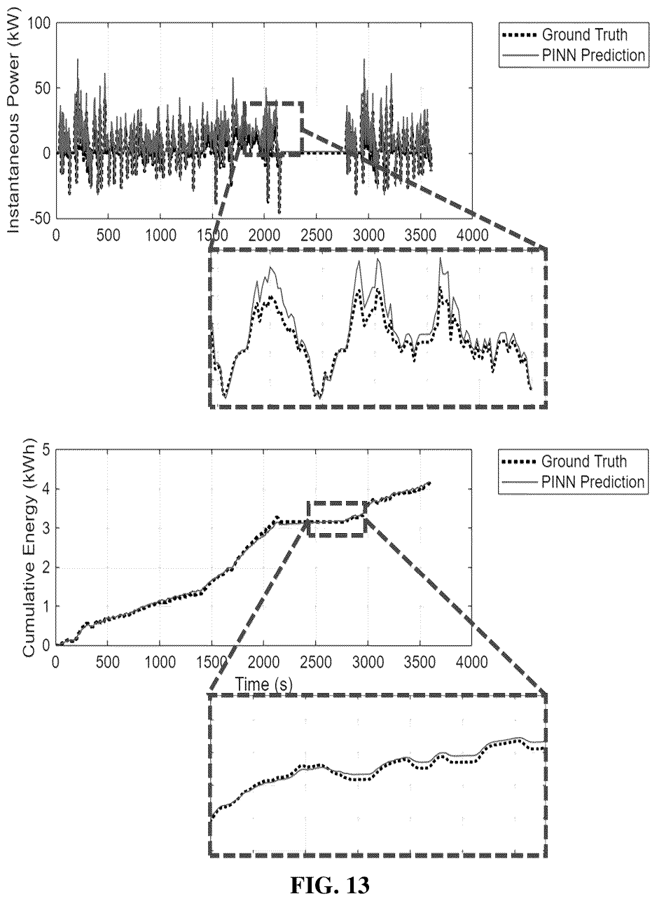

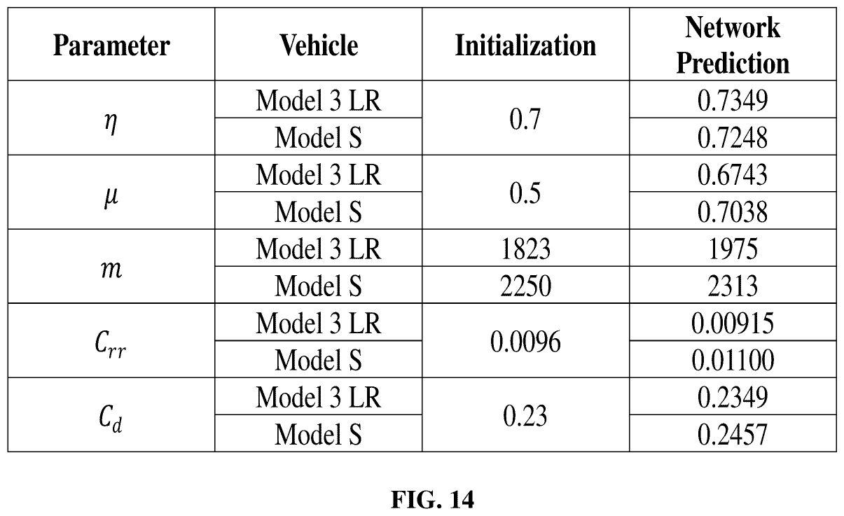

FIG. 12 is a battery power and energy prediction result of Tesla Model 3, and FIG. 13 is a battery power and energy prediction result of Tesla Model S.

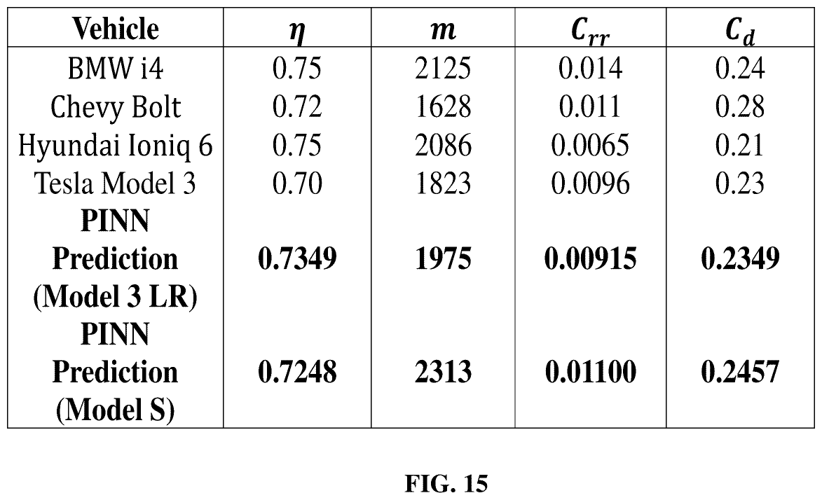

FIGS. 12 and 13 show that PINN prediction is almost consistent with actual log data of a test vehicle. Predicted energy consumption was consistent with an actual value of the log data and an RK4 integration result. FIGS. 14 and 15 show parameters predicted by the PINN, which are consistent with the log data and converge to realistic values. Interestingly, the predicted mass of Tesla Model 3 is 152 kg different from an initial empty vehicle weight. This is almost identical to a combined weight of two researchers and cargo during a test drive.

In conclusion, the PINN was successfully applied to predict EV power and energy consumption using only a vehicle speed and a time as inputs. The model not only achieved high accuracy in battery power prediction, but also accurately estimated real-world parameters such as vehicle mass and aerodynamic coefficients. These results highlight a potential of the PINN to improve EV energy management without relying on extensive sensor data. Even though the present invention focuses on a specific vehicle model, future research may include applying this model to a wider range of vehicles and driving conditions. In addition, integrating EV-PINN into real-time control may further optimize energy efficiency and path planning of the EV.

According to the present invention described above, a physics-informed neural network for predicting a dynamic parameter is derived, and instantaneous battery power and cumulative energy consumption may be accurately predicted based thereon, so that operating efficiency of the EV may be improved.

In addition, according to the present invention, it is possible to estimate actual dynamic conditions such as motor efficiency, regenerative braking efficiency, vehicle mass, aerodynamic drag, and rolling resistance of the EV, and integrate these parameters to more precisely predict cumulative energy consumption using only minimal sensor input such as vehicle speed and time.

According to the present invention described above, there are effects that a physics-informed neural network for predicting a dynamic parameter is derived, and instantaneous battery power and cumulative energy consumption may be accurately predicted based thereon, so that operating efficiency of the EV may be improved.

In addition, according to the present invention, it is possible to estimate actual dynamic conditions such as motor efficiency, regenerative braking efficiency, vehicle mass, aerodynamic drag, and rolling resistance of the EV, and integrate these parameters to more precisely predict cumulative energy consumption using only minimal sensor input such as a vehicle speed and a time.

Even though the invention made by the present inventor has been specifically described according to the embodiments, it is obvious to a person skilled in the art that the present invention is not limited to the embodiments and various modifications may be made without departing from the spirit thereof.

What is claimed is:

1. A method of estimating a dynamic coefficient of an electric vehicle and predicting energy consumption by utilizing speed log data and a physics-informed neural network, the method comprising steps of:
(a) collecting log data for predicting energy consumption of the electric vehicle in a processor for predicting energy consumption of the electric vehicle using a model including a physics-informed neural network;
(b) deriving a dynamic model for predicting battery power dynamics of the electric vehicle;
(c) setting a loss function of the dynamic model derived in the step (b);
(d) training and optimizing an energy consumption measurement model, which is a physics-informed neural network generated based on the set loss function; and
(e) predicting cumulative energy consumption using the energy consumption measurement model, which is the physics-informed neural network optimized in the step (d).

2. The method according to claim 1, wherein the step (a) comprises collecting the log data including a vehicle speed, a time, a battery voltage, and a battery current by connecting an OBD2 scanner to OBD2 mounted in the vehicle to the electric vehicle, and calculating the battery voltage and the battery current in the log data using Ohm's law to generate actual data of battery power.

3. The method according to claim 1, wherein the step (b) comprises using aerodynamic drag, rolling resistance, gravity, inertial force, and battery motor power as parameters for dynamic prediction.

4. The method according to claim 1, wherein the step (d) comprises shortening a training time by providing a realistic start point to the energy consumption measurement model, which is the physics-informed neural network, instead of searching an entire parameter space from start, the energy consumption measurement model being a model that takes a vehicle speed and a time as inputs and outputs battery power.

5. The method according to claim 4, wherein the energy consumption measurement model includes four fully connected subnetworks having 128 neurons, and the four subnetworks are optimized by sequentially learning parameters k₁, k₂, k₃, and k₄.
